(19) United States
(12) Patent Application Publication
(10) Pub. No.: US 2014/0262193 A1
(43) Pub. Date: Sep. 18, 2014

(54) EDGE RING COOLING MODULE FOR SEMI-CONDUCTOR MANUFACTURE CHUCK

(71) Applicant: Techest Co., Ltd., Gyeonggi-do (KR)

(72) Inventors: Chae Il IM, Gyeonggi-do (KR); Cheol Won Jang, Gyeonggi-do (KR)

(73) Assignee: Techest Co., Ltd., Gyeonggi-do (KR)

(21) Appl. No.: 14/204,549

(22) Filed: Mar. 11, 2014

(30) Foreign Application Priority Data
Mar. 13, 2013 (KR) 10-2013-0026834

(51) Int. Cl. H01L 21/67

(52) U.S. Cl. CPC H01L 21/67103
USPC 165/185

(57) ABSTRACT

An edge ring cooling module for semiconductor manufacturing chuck is provided which effectively cools the edge ring equipped in electrostatic chuck. The edge ring cooling module forcibly exhausts the heat of an edge ring (20) using an electronic cooling device (32) to top of a large-diameter portion (11) to effectively cool the edge ring (20) so that the temperature of the edge ring (20) is similar to that of top of a small-diameter portion (12) of a chuck body (10) to eventually improve the yield ratio while reducing the failure ratio.

### FIELD OF THE INVENTION

This invention is in reference to the new structure of edge ring cooling module for semiconductor manufacturing chuck designed to effectively cool the edge ring equipped in semiconductor manufacturing chuck.

### DISCUSSION OF RELATED ART

As shown in FIG. 1 and FIG. 2, semiconductor manufacturing electro static chuck (ESC) usually consists of chuck body (10), composed of disc-shaped large-diameter portion (11) and small-diameter portion (12) upwardly projected from top center of the above large-diameter portion (11) to form a disc shape of smaller diameter compared to the above large-diameter portion (11), and edge ring (20) inserted to the outside of the above small-diameter portion (12). The above chuck body (10) is furnished with electrostatic generator, not shown in the drawings, to generate static electricity to the above chuck body (10) and fix the wafer on top of the small-diameter portion (12).

ESC configuration is described well in a number of preceding documents as well as public patent 2003-0043013 thus a more detailed introduction shall be omitted.

In semiconductor manufacturing process using ESC, top of the above ESC is heated to a high temperature as wafer is fixed on top surface of ESC and processed by plasma.

Therefore the above chuck body (10) is designed to be equipped with cooling device using cooling water to cool top surface of chuck body (10) and keep a uniform temperature.

But the cooling device is supplied to the above chuck body (10) only thus cannot cool the above edge ring (20) enough.

Top surface temperature of edge ring (20) is uneven to cause high failure probability in wafer-processing semiconductor manufacturing progress.

The problem arises in all types of semiconductor manufacturing chucks equipped with edge ring on the top besides the above mentioned ESC.

Therefore, a new solution is required in order to resolve the issue.

### INVENTION

### Problem

The purpose of this invention is to provide edge ring cooling module to the new structure of semiconductor manufacturing chuck designed to effectively cool the edge ring furnished in the electrostatic chuck.

### Solution

In order to achieve the above purpose, this invention provides edge ring cooling module for semiconductor manufacturing chuck featuring lower thermal conductivity ring (31) corresponding to the above edge ring (20), electronic cooling device (32) closely fixed on top of the above lower thermal conductivity ring (31) and upper thermal conductivity ring (33) closely fixed on top of the above electronic cooling device (32) for the above lower thermal conductivity ring (31) to be inserted to the outside of the above small-diameter portion (12) to be closely fixed onto the top of the above large-diameter portion (11) and the above edge ring (20) to be closely fixed to top of the above upper thermal conductivity ring (33) in electro static chuck (ESC) consisting of chuck body (10), composed of disc-shaped large-diameter portion (11) and small-diameter portion (12) upwardly projected from top center of the above large-diameter portion (11) to form a disc shape of smaller diameter compared to the above large-diameter portion (11), and edge ring (20) inserted to the outside of the above small-diameter portion (12).

Another feature of edge ring cooling module for semiconductor manufacturing chuck of this invention is that the bore of the above lower thermal conductivity ring (31) and upper thermal conductivity ring (33) is bigger than the external diameter of the above small-diameter portion (12) that the inner circumferential surface of the above lower thermal conductivity ring (31) and upper thermal conductivity ring (33) is separated from the outer circumferential surface of the above small-diameter portion (12).

Another feature of edge ring cooling module for semiconductor manufacturing chuck of this invention includes ring-shaped insulator (34) to wrap outside of the above electronic cooling device (32) between the above lower thermal conductivity ring (31) and upper thermal conductivity ring (33) for upper and lower surfaces to be closely fixed respectively on the bottom and top of the above upper thermal conductivity ring (33) and lower thermal conductivity ring (31).

Another feature of edge ring cooling module for semiconductor manufacturing chuck of this invention is that the above lower thermal conductivity ring (31) and upper thermal conductivity ring (33) are made of ceramic, zirconium or quartz to prevent the above electronic cooling device (32) from the impact of plasma process.

### Effect

The edge ring cooling module for semiconductor manufacturing chuck in this invention forcibly exhausts the heat of edge ring (20) using electronic cooling device (32) to top of the above large-diameter portion (11) to effectively cool the edge ring (20) so that the temperature of edge ring (20) is similar to that of top of small-diameter portion (12) of chuck body (10) to eventually improve the yield ratio while reducing the failure ratio.

### BRIEF DESCRIPTION OF THE DRAWINGS

FIG. 1 is cross-sectional side view displaying traditional ESC,

FIG. 2 is cross-sectional side view showing decomposed state of traditional ESC,

FIG. 3 is cross-sectional side view describing ESC furnished with the edge ring cooling module according to this invention,

FIG. 4 is decomposition perspective view illustrating the edge ring cooling module for semiconductor manufacturing chuck according to this invention,

FIG. 5 is cross-sectional side view demonstrating decomposed state of ESC furnished with the edge ring cooling module according to this invention.

### DETAILED DESCRIPTION OF EXEMPLARY EMBODIMENTS

Hereafter, the invention is described in detail by the attached drawings.

FIG. 3 or FIG. 5 illustrates the edge ring cooling module for semiconductor manufacturing chuck according to this invention showing ESC Claim example to fix wafer using static electricity.

In the same way as before, the above ESC consists of chuck body (10), composed of disc-shaped large-diameter portion (11) and small-diameter portion (12) upwardly projected from top center of the above large-diameter portion (11) to form a disc shape of smaller diameter compared to the above large-diameter portion (11), and edge ring (20) inserted to the outside of the above small-diameter portion (12).

Then electrostatic generator and cooling device are furnished to the above chuck body (10), not shown in the drawings, to generate static electricity to the above chuck body (10), fix the wafer on top of the chuck body and effectively cool the chuck body (10) heated by plasma in the semiconductor manufacturing process.

According to this invention, edge ring cooling module (30) for semiconductor manufacturing chuck is closely fixed on bottom of the above edge ring (20) to exhaust the heat to top of the above large-diameter portion (11).

More specifically, the above edge ring cooling module (30) consists of lower thermal conductivity ring (31) corresponding to the above edge ring (20), electronic cooling device (32) closely fixed on top of the above lower thermal conductivity ring (31), upper thermal conductivity ring (33) closely fixed on top of the above electronic cooling device (32) and insulator (34) to wrap outside of the above electronic cooling device (32) for the above lower thermal conductivity ring (31) to be inserted to the outside of the above small-diameter portion (12) to be closely fixed onto the top of the above large-diameter portion (11) and the above edge ring (20) to be closely fixed to top of the above upper thermal conductivity ring (33).

The above lower thermal conductivity ring (31) is made of material with high thermal conductivity and plasma blocking feature.

Preferably, the above lower thermal conductivity ring (31) is made of quartz.

Several pieces of the above electronic cooling device (32), designed to absorb the heat of the top and exhaust to the bottom when electricity is applied, are placed at regular intervals on top of the above lower thermal conductivity ring (31).

The above upper thermal conductivity ring (33) is made of material with high thermal conductivity and plasma blocking feature.

Preferably, the above upper thermal conductivity ring (33) is made of ceramic or zirconium.

The above insulator (34) is made of ceramic, zirconium or quartz of plasma blocking feature like the lower thermal conductivity ring (31) and upper thermal conductivity ring (33) mentioned above, as shown in FIG. 3, the bore is bigger than the circle of the above electronic cooling device (32) for upper and lower surfaces to be closely fixed respectively on the bottom and top of the above upper thermal conductivity ring (33) and lower thermal conductivity ring (31).

The external diameter of the above lower thermal conductivity ring (31) and upper thermal conductivity ring (33) corresponds to that of the above large-diameter portion (11) and the bore is bigger than the external diameter of the above small-diameter portion (12) for the inner circumferential surfaces of the above lower thermal conductivity ring (31) and upper thermal conductivity ring (33) to separate from the external circumferential surface of the above small-diameter portion (12) as shown in FIG. 3.

ESC is completely assembled by closely fixing edge ring cooling module (30) for the bottom of the above lower thermal conductivity ring (31) to be firmly fastened on top of the above large-diameter portion (11) then tightly attaching the above edge ring (20) on top of the above edge ring cooling module (30).

When electricity is applied, the above electronic cooling device (32) absorbs the heat of the above upper thermal conductivity ring (33) then emits to top of the large-diameter portion (11) thru the above lower thermal conductivity ring (31).

The heat of edge ring (20) caused by plasma during semiconductor manufacturing process is discharged on top of large-diameter portion (11) of chuck body (10) thru the above upper thermal conductivity ring (33), electronic cooling device (32) and lower thermal conductivity ring (31) to be eventually cooled by the cooling devices furnished in the above chuck body (10).

Thus the edge ring cooling module for semiconductor manufacturing chuck forcibly exhausts the heat of edge ring (20) using electronic cooling device (32) to top of the above large-diameter portion (11) to effectively cool the edge ring (20) so that the temperature of edge ring (20) is similar to that of top of small-diameter portion (12) of chuck body (10) to eventually improve the yield ratio while reducing the failure ratio.

The bore of the above lower thermal conductivity ring (31) and upper thermal conductivity ring (33) is bigger than the external diameter of the above small-diameter portion (12) that the inner circumferential surface of the above lower thermal conductivity ring (31) and upper thermal conductivity ring (33) is separated from the outer circumferential surface of small-diameter portion (12) to eventually prevent cooling performance degradation by cutting the heat transfer from small-diameter portion (12) to the above lower thermal conductivity ring (31) and upper thermal conductivity ring (33).

Ring-shaped insulator (34) between the above lower thermal conductivity ring (31) and upper thermal conductivity ring (33) wraps outside of the electronic cooling device (32) to prevent operational error or damage of electronic cooling device (32) by plasma thru vacancy around the circumference of the above lower thermal conductivity ring (31) and upper thermal conductivity ring (33).

Further, the above lower thermal conductivity ring (31) and upper thermal conductivity ring (33) are made of ceramic, zirconium or quartz of high thermal conductivity and plasma blocking feature to prevent the impact of plasma on the electronic cooling device (32) thru the lower thermal conductivity ring (31) and upper thermal conductivity ring (33).

In this implementation, the above edge ring cooling module is applied to ESC, however, the edge ring cooling module of this invention is applicable to all types of chuck with edge ring on top besides ESC.

In this experiment, several pieces of electronic cooling device (32) are placed at regular intervals on top of the above lower thermal conductivity ring (31) but a ring-shaped electronic cooling device (32) corresponding to top of the above lower thermal conductivity ring (31) is also available.

### CODE DESCRIPTION

| | |
|---|---|
| 10. Chuck body | 11. Large-diameter portion |
| 12. Small-diameter portion | 20. Edge ring |
| 30. Edge ring cooling module | 31. Lower thermal conductivity ring |
| 32. Electronic cooling device | 33. Upper thermal conductivity ring |
| 34. Insulator | |

1. An edge ring cooling module for semiconductor manufacturing chuck, comprising:
a chuck body (10), including a disc-shaped large-diameter portion (11) and a small-diameter portion (12) upwardly projected from a top center of the large-diameter portion (11) to form a disc shape having a diameter smaller than a diameter of the large-diameter portion (11),
a ring-shaped edge ring (20) connected to and surrounding an outer circumference of the small-diameter portion (12),
a lower thermal conductivity ring (31) formed in a ring shape corresponding to the ring-shaped edge ring (20),
an electronic cooling device (32) fixed on and in contact with a top of the lower thermal conductivity ring (31), and
an upper thermal conductivity ring (33) fixed on and in contact with a top of the electronic cooling device (32), the upper thermal conductivity ring (33) having a ring shape corresponding to the ring-shaped edge ring (20),
wherein the small-diameter portion (12) is inserted within an inner circumferential surface of the lower thermal conductivity ring (31), and the lower thermal conductivity ring (31) is fixed onto and comes in contact with a top of the large-diameter portion (11), and
wherein the edge ring (20) is fixed to and comes in contact with a top of the above upper thermal conductivity ring (33).

2. The edge ring cooling module of claim 1, wherein:
an inner diameter of the lower thermal conductivity ring (31) is bigger than the diameter of the small-diameter portion (12), and an inner diameter of the upper thermal conductivity ring (33) is bigger than the diameter of the small-diameter portion (12), and
the inner circumferential surface of the lower thermal conductivity ring (31) and an inner circumferential surface of upper thermal conductivity ring (33) are spaced apart from the outer circumferential surface of the small-diameter portion (12).

3. The edge ring cooling module of claim 1, further comprising
a ring-shaped insulator (34) surrounding an outer circumferential surface of the electronic cooling device (32), and being disposed and fixed between the above lower thermal conductivity ring (31) and upper thermal conductivity ring (33), the insulator (34) having an upper surface in contact with a bottom of the upper conductivity ring (33) and a lower surface in contact with a top of the lower thermal conductivity ring (31).

4. The edge ring cooling module of claim 1, wherein:
the lower thermal conductivity ring (31) and upper thermal conductivity ring (33) are made of ceramic, zirconium or quartz, which allows the electronic cooling device (32) to be protected from an impact of plasma used in semiconductor manufacturing process.
